(19) United States
(12) Patent Application Publication
(10) Pub. No.: US 2013/0060508 A1
(43) Pub. Date: Mar. 7, 2013

(54) TEST CONDITION SETTING METHOD, CURRENT VARIATION TESTING METHOD, AND INFORMATION PROCESSING APPARATUS

(71) Applicant: Shinsuke TERANISHI, Yokohama (JP)

(72) Inventor: Shinsuke TERANISHI, Yokohama (JP)

(73) Assignee: FUJITSU LIMITED, Kawasaki-shi (JP)

(21) Appl. No.: 13/535,516

(22) Filed: Jun. 28, 2012

(30) Foreign Application Priority Data
Sep. 7, 2011 (JP) 2011-195309

(51) Int. Cl. G01R 31/42; G06F 19/00

(52) U.S. Cl. 702/124

(57) ABSTRACT

A master CPU makes an execution interval b, during which CPUs are operated, common to CPUs including the master CPU and makes a stop interval a, during which the CPUs are stopped, different for each of the CPUs including the master CPU. As a result, the lengths of cycle intervals c of the CPUs constituted by the execution interval b and the stop interval a allow the ratio between the lengths of the cycle intervals c of any CPUs to be represented by two integers that are coprime to each other. Setting such lengths of the cycle intervals c of the CPUs achieves the synchronism between the shifts of all of the CPUs from a stopped state to an in-operation state and from the in-operation state to the stopped state.

### CROSS-REFERENCE TO RELATED APPLICATION

This application is based upon and claims the benefit of priority of the prior Japanese Patent Application No. 2011-195309, filed on Sep. 7, 2011, the entire contents of which are incorporated herein by reference.

### FIELD

The embodiments described herein are related to a technology used for a current variation test that varies a current used by an information processing apparatus.

### BACKGROUND

An information processing apparatus represented by a computer is typically provided with a plurality of power supply circuits. Accordingly, currents from the power source are supplied via one or more other power supplies to each load provided at the information processing apparatus. In this way, supplying a current via one or more power supplies allows a necessary voltage to be applied to each individual load. For convenience, the power source will hereinafter be referred to as the “power supply unit” and the power supplies other than the power supply unit will be hereinafter referred to as “power supply circuits” to clarify the difference.

Currents used by loads provided at an information processing apparatus, e.g., a processor such as a CPU (CPU: Central Processing Unit), a memory (or a memory module), and an I/O (Input/Output) controller, are not always constant. Accordingly, currents actually supplied from the power supply unit via the power supply circuit to the information processing apparatus vary depending on the situation. Accordingly, the power supply unit needs to prevent the voltage from indicating an abnormal level caused by used currents, i.e., caused by power consumption. In particular, an information processing apparatus used as, for example, a server is required to have a high reliability, and hence the power supply unit needs to assure stable operations of the information processing apparatus. Accordingly, current variation tests that vary currents used by information processing apparatuses have been conventionally performed. By performing the current variation tests, it is possible to determine whether the power supply unit will maintain a suitable voltage or not, irrespective of whether the power consumption of the information processing apparatus varies or not.

A CPU provided at an information processing apparatus is typically capable of being stopped (power-off) and started (power-on) at optional timings so that the power consumption can be reduced. The power consumption of the CPU is large from among loads provided at the information processing apparatus. Accordingly, in one conventional current variation testing method, the CPU is started and stopped repeatedly on a defined cycle to significantly vary the current used by the information processing apparatus.

In such a conventional current variation testing method, all CPUs have been started and stopped at the same timing. Accordingly, in a test directed to an information processing apparatus provided with a plurality of CPUs, in order to cause the maximum current variation, the operation cycles of the CPUs including starting and stopping need to be identical with each other, i.e., the operation cycles need to be in synchrony with each other.

The timings of starting and stopping the CPUs are set by the CPUs, i.e., set via software control. In an information processing apparatus provided with a plurality of CPUs, each CPU sets the timings of starting and stopping itself via software control. In current variation tests, each CPU needs to obtain data for setting the timings of starting and stopping via software control. For such a reason, it is very difficult to synchronize the operation cycles of the CPUs. Therefore, it is preferable that the maximum variation in the current used by the information processing apparatus be readily caused to occur.

### SUMMARY

According to an aspect of the embodiment, a test condition setting method for setting a condition of a current variation test that varies a current supplied from a power supply circuit provided in an information processing apparatus including a plurality of processors, includes: setting, at a prime number ratio, a ratio between lengths of cycle intervals of the plurality of processors used in the current variation test, the cycle intervals including operation intervals during which an in-operation state is maintained upon the processors being started one time and stop intervals during which a stopped state is maintained upon the processors being stopped one time; and setting the lengths of the cycle intervals each set for each of the processors as the condition of the current variation test of the plurality of processors.

According to an aspect of the embodiment, a current variation testing method for performing a current variation test that varies a current supplied from a power supply circuit provided in an information processing apparatus including a plurality of processors, includes: setting, as a condition of the plurality of processors for the current variation test, lengths of cycle intervals of the plurality of processors at lengths allowing a ratio between lengths of cycle intervals of any two of the plurality of processors to be represented by two integers that are coprime to each other, the cycle intervals including operation intervals during which an in-operation state is maintained upon the processors being started one time and stop intervals during which a stopped state is maintained upon the central processing units being stopped one time; and performing the current variation test by starting and stopping the plurality of processors in accordance with the set lengths of the cycle intervals.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates the configuration of an information processing apparatus in accordance with the present embodiment.

FIG. 2 illustrates the circuit configuration of a CPU.

FIG. 3 illustrates a method for implementing a current variation testing method in accordance with the present embodiment.

FIG. 4 illustrates exemplary contents of a CPU control list.

FIG. 5 illustrates start/stop control of a CPU.

FIG. 6 is a timing chart (pattern 1) indicating an example of a time change in a state of each CPU.

FIG. 7 is a timing chart (pattern 2) indicating an example of a time change in a state of each CPU.

FIG. 8 is a flowchart indicating a flow of a process executed by each CPU in accordance with a test control program according to the present embodiment.

FIG. 9 is a flowchart of a condition setting process.

### DESCRIPTION OF EMBODIMENTS

In the following, the embodiment of the present invention will be described in detail with reference to the drawings.

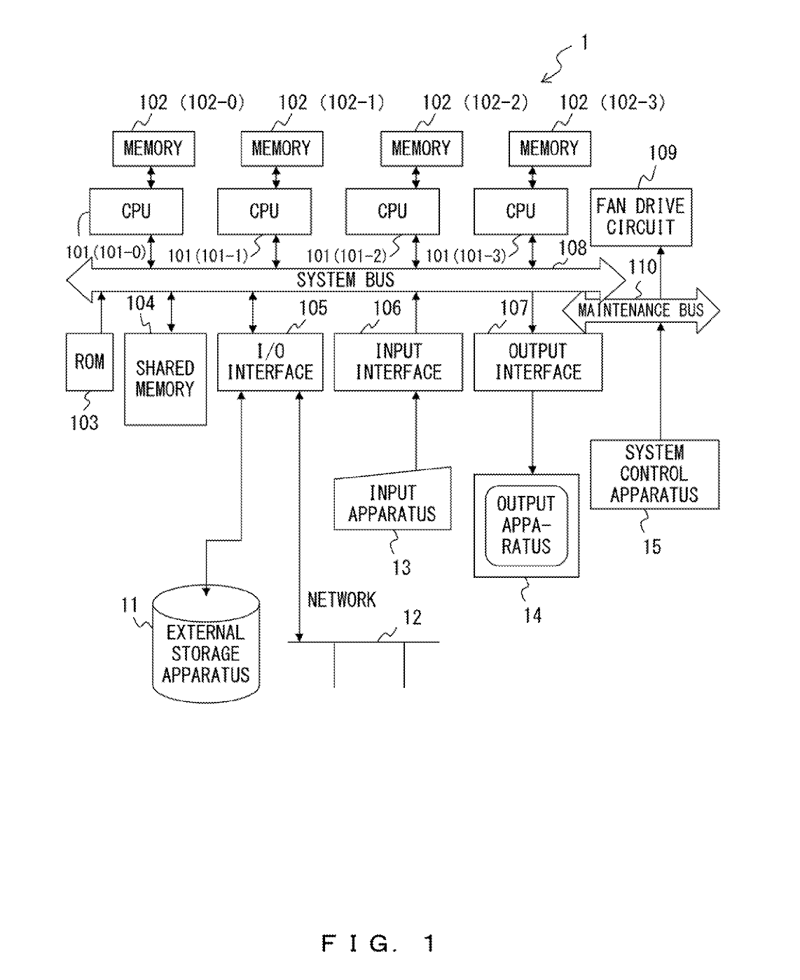

FIG. 1 illustrates the configuration of an information processing apparatus in accordance with the present embodiment. An information processing apparatus 1 is used as, for example, one computer (or server). The information processing apparatus 1 may be a server blade configuring a server or an information processing apparatus that functions as one computer like a module apparatus such as a system board. A current variation testing method and a test condition setting method in accordance with the present embodiment are applied to the information processing apparatus 1.

The information processing apparatus 1 indicated in FIG. 1 is provided with four processors, CPUs 101 (101-0 to 101-3), and a memory (or memory module) 102 (102-0 to 102-3) is connected to each of the CPUs 101. A ROM (Read Only Memory) 103, a shared memory 104, an I/O interface 105, an input interface 106, and an output interface 107 are connected to the CPUs 101 via a system bus 108. A fan drive circuit 109 that drives a fan (or a motor) (not illustrated) is connected to a maintenance bus 110.

In the aforementioned configuration, the ROM 103 stores a BIOS (Basic Input/Output System) code executed by, for example, the CPUs 101. The shared memory 104 is used to store data to be shared between, for example, the CPUs 101. The I/O interface 105 receives a data input from and outputs data to external equipment. FIG. 1 indicates an external storage apparatus 11 and a network 12 as external equipment.

The input interface 106 is capable of inputting an instruction input via an input apparatus 13. The input apparatus 13 corresponds to, for example, a console or an operation apparatus for user operations such as a keyboard and a pointing device. The output interface 107 is an interface for outputting data to an output apparatus 14 such as a display apparatus.

The maintenance bus 110 is used to externally manage an operation of the fan drive circuit 109 and the power supply of the information processing apparatus 1. In addition to the fan drive circuit 109, the maintenance bus 110 has an external system control apparatus 15 connected to it. The system control apparatus 15 is another information processing apparatus for managing, for example, the entirety of the information processing apparatus 1.

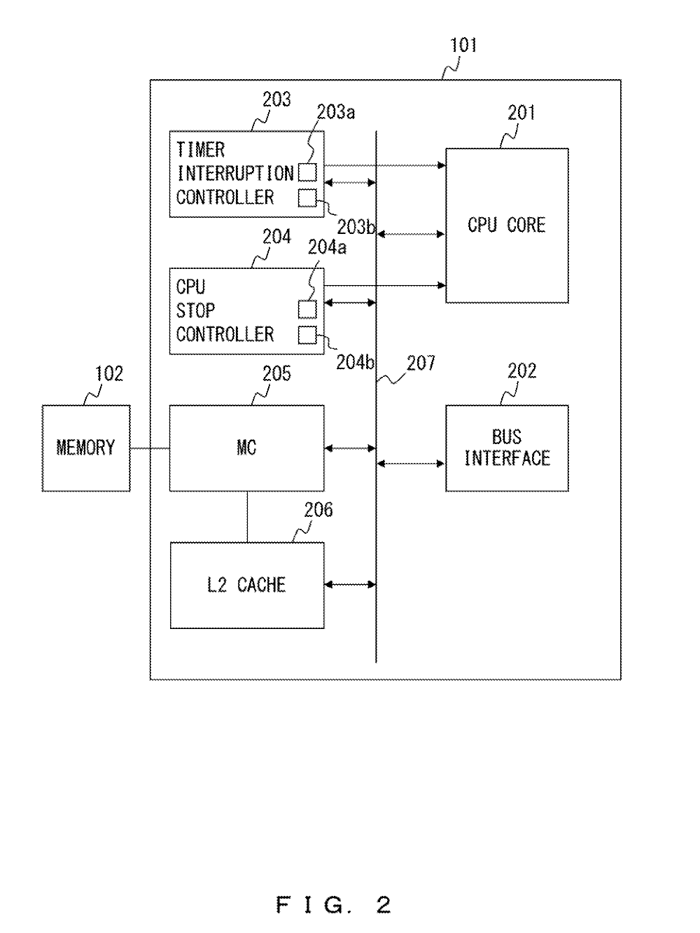

FIG. 2 illustrates the circuit configuration of a CPU. As illustrated in FIG. 2, each of the CPUs 101 is configured so that a CPU core 201, a bus interface 202, a timer interruption controller 203, a CPU stop controller 204, an MC (Memory Controller) 205, and a secondary cache (or L2 (Level 2) cache) 206 are connected to an internal bus 207.

The CPU core 201 performs arithmetic processing for executing various commands. The bus interface 202 transmits and receives data via the system bus 108.

In accordance with a designated timing, the timer interruption controller 203 outputs a designated kind of interruption signal to the CPU core 201. The interruption signal includes a signal for returning (or shifting) the CPUs 101 from a stopped state to an in-operation state (or an executed state). The stopped state is, for example, a suspended state. The interruption signal for returning the CPUs 101 from the stopped state to the in-operation state will be hereinafter referred to as a “return interruption signal”. Unless otherwise specified, an interruption signal indicates a return interruption signal.

The timer interruption controller 203 includes a register 203a and a counter 203b. The register 203a and the counter 203b are for outputting a return interruption signal. The register 203a is used to retain a value to be compared with, for example, a count value of the counter 203b, and the counter 203b increments an initial value, e.g., 0, on an as-needed basis. An interruption signal (or a return interruption signal) is output when, for example, the value of the register 203a is identical with the count value of the counter 203b. The value of the counter 203b is reset to the initial value after the interruption signal is output. Accordingly, the interval from the start of counting by the counter 203b to the output of the return interruption signal may be designated by a value (or data) retained by the register 203a.

The CPU stop controller 204 is capable of outputting, to the CPU core 201, a control signal (or an interruption signal) that shifts the CPUs 101 from the in-operation state to the stopped state, and the controller includes a register 204a and a counter 204b. The register 204a and the counter 204b are for outputting the control signal. The register 204a is used to retain a value to be compared with, for example, a count value of the counter 204b, and the counter 204b increments an initial value, e.g., 0, on an as-needed basis. The control signal is output when, for example, the value of the register 204a is identical with the count value of the counter 204b. The value of the counter 204b is reset to the initial value after the control signal is output. Accordingly, the interval from the start of counting by the counter 204b to the output of the control signal may be designated by a value (or data) retained by the register 204a.

The counter 203b of the timer interruption controller 203 and the counter 204b of the timer interruption controller 203 start counting, under control of the CPU core 201. The counters 203b and 204b are operated in accordance with, for example, a clock of a fixed cycle (e.g., the frequency of a system clock divided by a predetermined number, which will be referred to as a “timer clock” hereinafter). Accordingly, the output timings of the return interruption signal and the control signal may be adjusted in units of the cycles of the timer clock.

The MC 205 accesses the memory 102 in accordance with an instruction from the CPU core 201 or an instruction from another CPU 101 given via the internal bus 207 and the bus interface 202. The secondary cache 206 is used to save frequently used data.

The current variation testing method and the test condition setting method in accordance with the present embodiment are assumed to be applied to the information processing apparatus 1 provided with a plurality of CPUs 101 as described above. In the following, the methods applied to the information processing apparatus 1 will be described in detail.

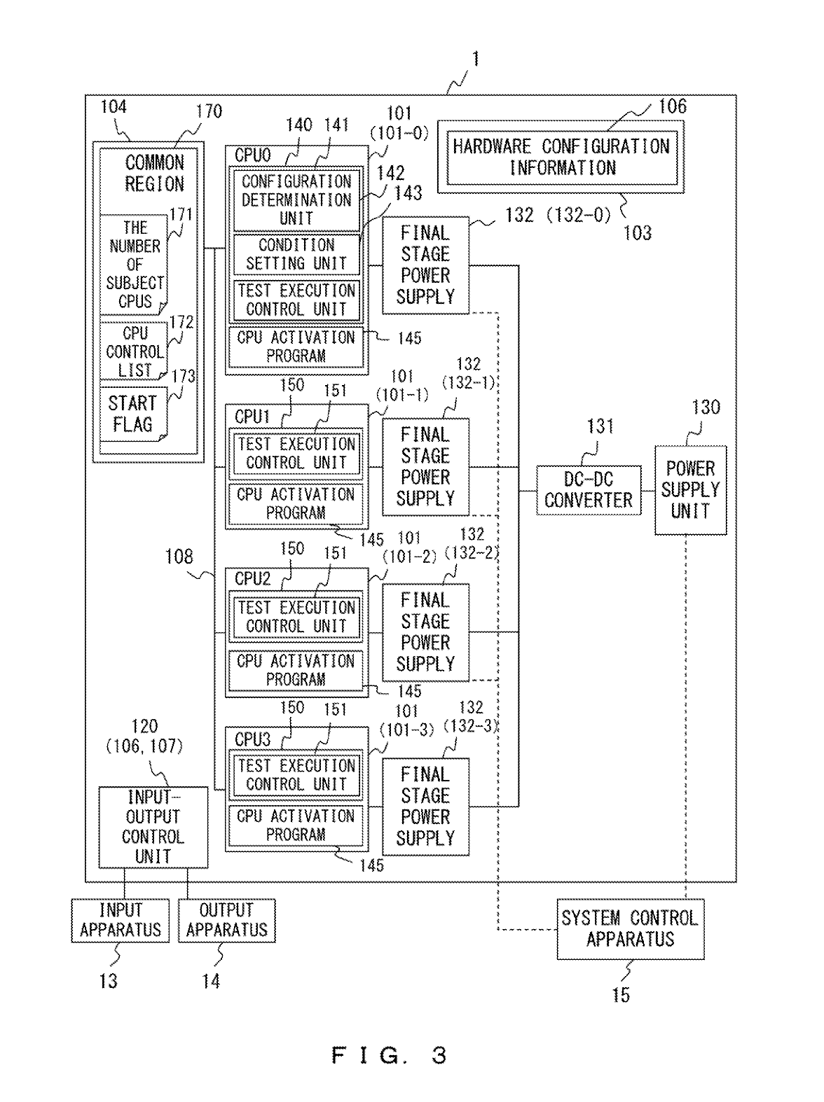

FIG. 3 illustrates a method for implementing the current variation testing method in accordance with the present embodiment.

A current is supplied from a power supply unit 130 to the information processing apparatus 1 provided with four CPUs 101. A power supply circuit (“final stage power supply” in FIG. 3 (POL: Point Of Load)) 132 (132-0 to 132-3) is provided for each of the four CPUs, and a current is supplied from the power supply unit 130 via a DC-DC converter 131 to each of the power supply circuits 132.

The system control apparatus 15 controls ON/OFF of the power supply circuits 132 and the power supply unit 130 via, for example, a signal line. Meanwhile, the system control apparatus 15 may obtain condition data such as a voltage value and a current value from the power supply unit 130 on an as-needed basis. Accordingly, when a current variation test is performed, the system control apparatus 15 functions as an apparatus that monitors the state of the power supply unit 130 and obtains test data such as a voltage value and a current value. The current variation test is performed while the power supply unit 130 and all of the power supply circuits 132 are being put in an on-state.

When the current variation test is performed, the CPUs 101 each execute a test control program 140 or 150 for performing the current variation test and a CPU activation program 145. The CPU activation program 145 is a program for efficiently using resources of the CPUs 131 so as to increase the power consumption of the CPUs 131. The test control programs 140 and 150 realize the current variation test using the CPU activation program 145.

In the current variation test, one of the four CPUs 101 functions as a master and the other three function as slaves. The test control program 140 is executed by the CPU 101 that functions as a master, and the test control program 150 is executed by the CPUs 101 that function as slaves. FIG. 3 indicates that the CPU 101-0 executes the test control program 140 and the CPUs 101-1 to 101-3 execute the test control program 150. In the following, the CPU 101-0 that executes the test control program 140 will be referred to as a “master CPU 101” when the CPU 101-0 is distinguished from the other CPUs 101. The CPUs 101-1 to 101-3 that execute the test control program 150 will be referred to as “slave CPUs 101” when the CPUs 101-1 to 101-3 are distinguished from the master CPU 101.

The test control program 140 includes a configuration determination unit 141, a condition setting unit 142, and a test execution control unit 143 as functions.

While the current variation test is being performed, the CPUs 101 each repeat the stopped state and the in-operation state in turn. In the present embodiment, the interval in which the stopped state is maintained (hereinafter referred to as a “stop interval”) and the interval in which the in-operation state is maintained (hereinafter referred to as an “operation interval” or “execution interval”) are used as test conditions for performing the current variation test, and these conditions are different for each of the CPUs 101. The configuration determination unit 141 determines the number of CPUs of the information processing apparatus 1 that are needed to set a test condition for each of the CPUs 101. The number of CPUs is determined by referring to hardware configuration information 160 of the information processing apparatus 1 stored in the ROM 103. The determined number of CPUs is stored, as the number of subject CPUs 171, in a shared region 170 reserved in, for example, the shared memory 104. The hardware configuration information 160 also includes information other than the number of CPUs. The shared region 170 may be reserved in a storage apparatus other than the shared memory 104, e.g., in the memory 102-0 connected to the master CPU 101.

The condition setting unit 142 sets, for each of the CPUs 101, the stop interval and the execution interval by referring to the number of subject CPUs 171. The CPUs' 101 transition to a stopped state and transition from the stopped state to an executed state are made using the CPU stop controller 204 and the timer interruption controller 203. Accordingly, the stop interval and the execution interval are set by numerical values (or integer values) represented in units of the cycles of the timer clock. Since one cycle is formed by one stop interval and one execution interval, the interval formed by one stop interval and one execution interval will be hereinafter referred to as a “cycle interval”.

The stop interval, the execution interval, and the cycle interval (or values of these intervals) set for each of the CPUs 101 by the condition setting unit 142 are stored in the shared region 170 as a CPU control list 172. The stop interval, the execution interval, and the cycle interval (or values of these intervals) set for each CPU will be hereinafter referred to as “CPU control information”. A particular piece of CPU control information directed to the CPU 101-0 will be referred to as “CPU0 control information”. This is also true for the other pieces of CPU control information.

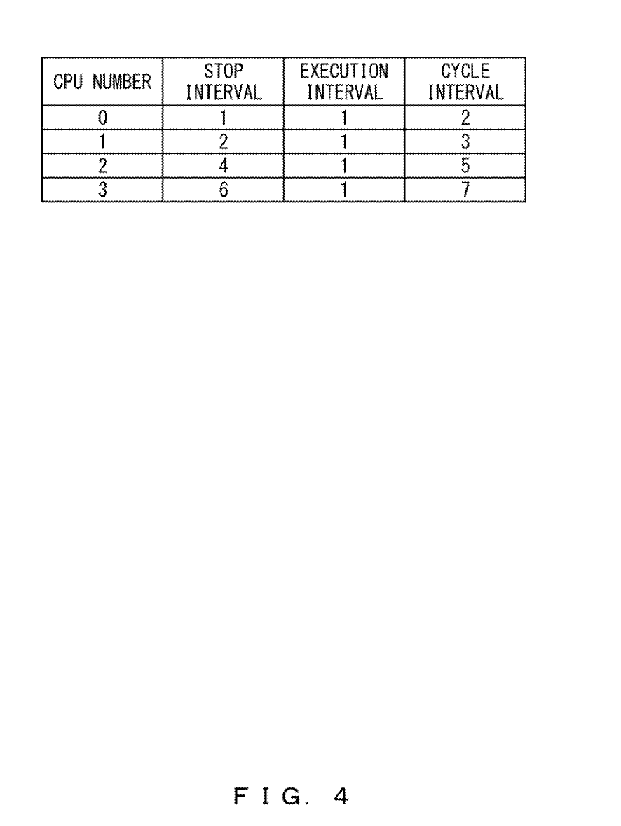

FIG. 4 illustrates exemplary contents of a CPU control list. As indicated in FIG. 4, the CPU control information is stored for each of the CPUs 101. CPU numbers are identification information of the CPUs 101, and the numbers correspond to, for example, a numeric value to the right of “101-”. That is, as an example, the CPU number of the CPU 101-0 is “0”.

In the example illustrated in FIG. 4, the execution intervals of all of the CPUs 101 are the same value, “1”, and the stop interval is different for each of the CPUs 101. Making the stop interval different for each of the CPUs 101 allows the ratio between the cycle intervals of any two of the CPUs 101, i.e., the ratio between the cycle intervals of any two CPUs from among the CPUs 101, to be represented using two integers that are coprime to each other. In the present embodiment, the values of the cycle intervals set for the CPUs 101 are different prime numbers so that the ratio between the cycle intervals of any two CPUs becomes two integers that are coprime to each other. Two integers that are coprime to each other are two integers whose common divisors are “+1” and “−1” only. Accordingly, two different prime numbers are coprime to each other.

After the condition setting unit 142 saves the CPU control list 172 in the shared region 170, the test execution control unit 143 stores a start flag 173 representing performing of the current variation test in the shared region 170 and starts the CPU activation program 145. Meanwhile, the test execution control unit 143 extracts the CPU0 control information of the master CPU 101 in the CPU control list 172. In accordance with the CPU0 control information, the test execution control unit 143 stores values in the register 203a of the timer interruption controller 203 and the register 204a of the CPU stop controller 204 and causes the counters 203b and 204b to start counting. After this, the executed state of the CPU activation program 145 is maintained until an end timing of the current variation test comes. The coming of the end timing of the current variation test indicates, for example, the passage of a test time that is set in advance or an operator giving an end instruction. When the end timing comes, the test execution control unit 143 rewrites, for example, the start flag 173 to indicate that the current variation test has ended. Rewriting the start flag 173 to indicate performing of the current variation test will hereinafter be referred to as “set (setting)”, and rewriting the start flag 173 to indicate that the current variation test has ended will hereinafter be referred to as “reset (resetting)”.

In the meantime, a test execution control unit 151 of a slave CPU 101 recognizes the performing timing or the end timing of the current variation test by polling (or monitoring) the start flag 173 of the shared region 170. When the test execution control unit 151 recognizes the performing timing of the current variation test, i.e., the setting of the start flag 173, the test execution control unit 151 starts the CPU activation program 145. Meanwhile, the test execution control unit 151 refers to the CPU control list 172, stores values in the register 203a of the timer interruption controller 203 and the register 204a of the CPU stop controller 204, and causes the counters 203b and 204b to start counting. After this, the executed state of the CPU activation program 145 is maintained until the end timing of the current variation test comes, i.e., until the start flag 173 is reset.

In, for example, FIG. 1, a program group including the test control programs 140 and 150 and the CPU activation program 145 is stored in the external storage apparatus 11 or an external apparatus connected via the network 12. Under the situation in which each CPU 101 executes a BIOS code, the operator operates the input apparatus 13 to designate a place where the program group is to be saved and causes the information processing apparatus 1 to access the program group. Upon the access being made, each CPU 101 loads the test control program 140 or 150 and the CPU activation program 145 into the memory 102. This allows each CPU 101 to execute the test control program 140 or 150. The information processing apparatus 1 in accordance with the present embodiment is achieved via each CPU 101 executing the test control program 140 or 150.

A program may be provided for loading the test control program 140 or 150 and the CPU activation program 145 into each CPU 101. The method for enabling the current variation test to be performed is not particularly limited.

The place where the program group is to be saved may be designated while looking at the output apparatus 14. Accordingly, an input-output control unit 120 in FIG. 3 corresponds to a combination of the input interface 106 and the output interface 107 in FIG. 1.

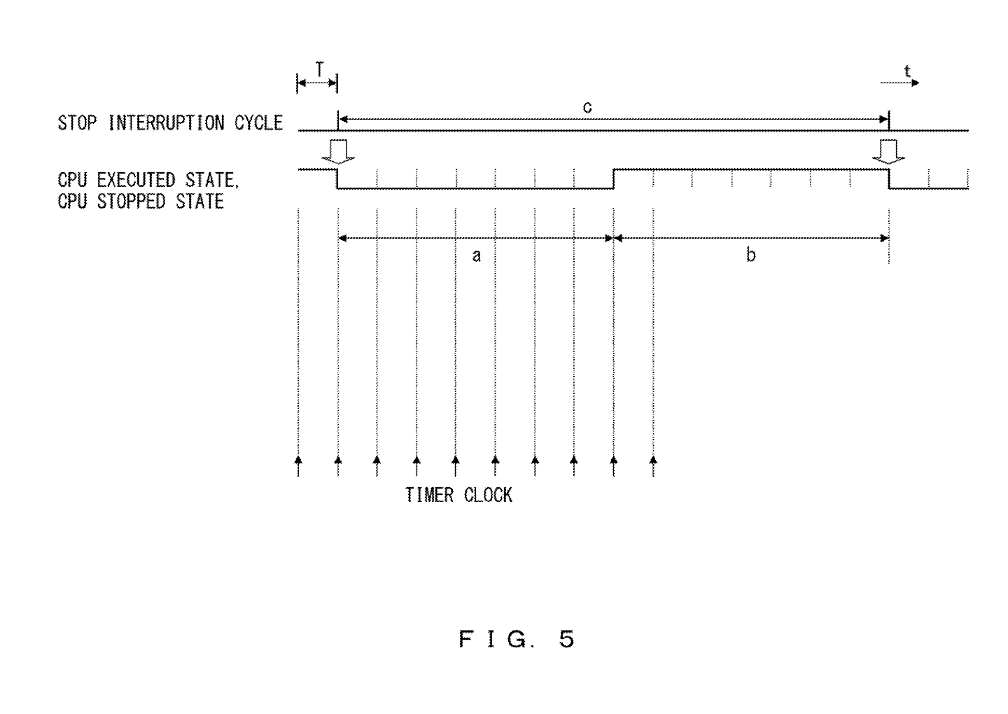

FIG. 5 illustrates start/stop control of a CPU. In FIG. 5, “stop interruption cycle” represents a timing of an output of a control signal by the CPU stop controller 204 on the temporal axis, and “CPU executed state, CPU stopped state” indicates a change in state of the CPU 101 on the temporal axis. The timings at which the CPU stop controller 204 outputs the control signal and the in-operation state of the CPU 101 are both indicated as H(High) level. “a” indicates the stop interval; “b”, the execution interval; “c”, the cycle interval. “T” represents one cycle of the timer clock.

As described above, the signals output from the timer interruption controller 203 and the CPU stop controller 204 to the CPU core 201 cause each CPU 101 to shift from the in-operation state to the stopped state and from the stopped state to the in-operation state. The interval from the time at which each CPU 101 shifts to the stopped state to the time at which each CPU 101 shifts to the stopped state again is equal to the cycle interval c. Accordingly, the CPU core 201 of each CPU 101 stores a value representing the cycle interval c in the register 204a of the CPU stop controller 204.

The interval from the time at which each CPU 101 shifts to the in-operation state to the time at which each CPU 101 shifts to the in-operation state again is also equal to the cycle interval c. Accordingly, the CPU core 201 of each CPU 101 stores a value representing the cycle interval c in the register 203a of the timer interruption controller 203. The stop interval a and the execution interval b are achieved by controlling count start timings of the counters 203b of the timer interruption controller 203 and the counter 204b of the CPU stop controller 204. By controlling the count start timings, the timer interruption controller 203 is caused to output an interruption signal after the passage of the stop interval a since an output of the control signal from the CPU stop controller 204. As a result, in accordance with CPU control information that has been set, each CPU 101 may shift from the in-operation state to the stopped state and from the stopped state to the in-operation state.

In the present embodiment, one of the execution interval b and the stop interval a is common to all of the CPUs 101 and the other is different for each of the CPUs 101, so that the ratio between the cycle intervals c of any two of the CPUs 101 can be represented using two integrals that are coprime to each other. In the cycle interval c setting the execution interval b and the stop interval a in this way, the time difference in the common interval between the CPUs 101 changes as time passes. Since the ratio between the cycle intervals c of any two of the CPUs 101 may be represented using two integrals that are coprime to each other, the time difference variously changes within the range from 0 to a value that is lower than the lower of the two integrals.

The current variation test is started via the master CPU 101 setting the start flag 173. After the start flag 173 is set, each of the slave CPUs 101 individually checks the set start flag 173. Accordingly, the timing of starting the current variation test is not only different between the master CPU 101 and each of the slave CPUs 101 but also different between the slave CPUs 101. However, setting the cycle interval c as described above for each CPU 101 causes a situation in which the time difference in the execution interval b or the stop interval a between the CPUs 101, which would be made by such a timing difference, becomes 0. The maximum variation in the direction of current increase or the maximum variation in the direction of current decrease is caused by such a situation. Accordingly, the current variation test that causes the maximum current variation may be performed.

The situation occurs without the operations of the CPUs 101 being synchronized. Conventionally, it has taken about one week to achieve such synchronization. Accordingly, in comparison with current variation tests involving synchronization, the current variation test in accordance with the present invention may be performed extremely readily.

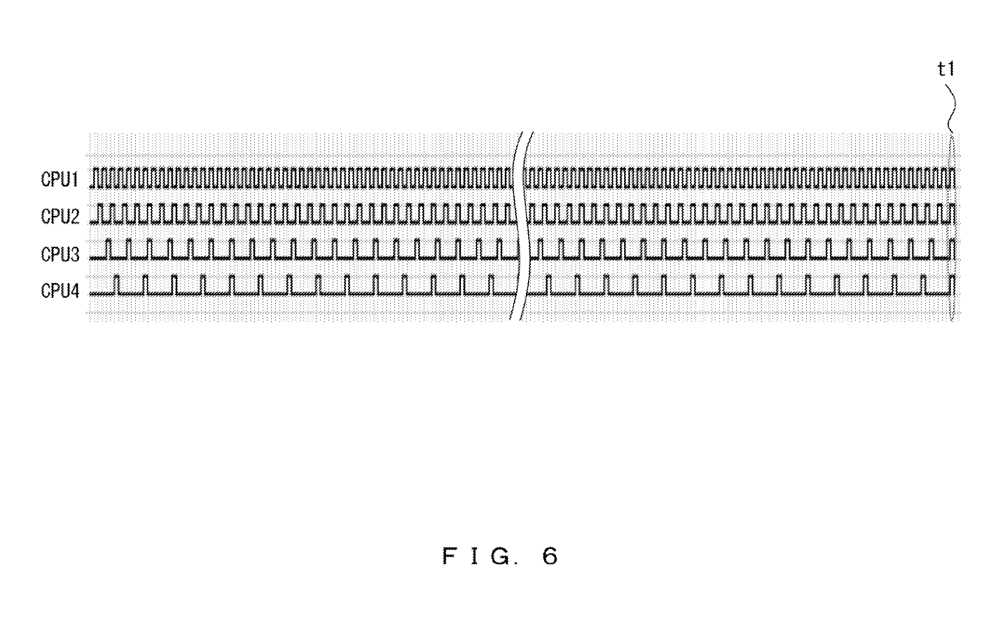

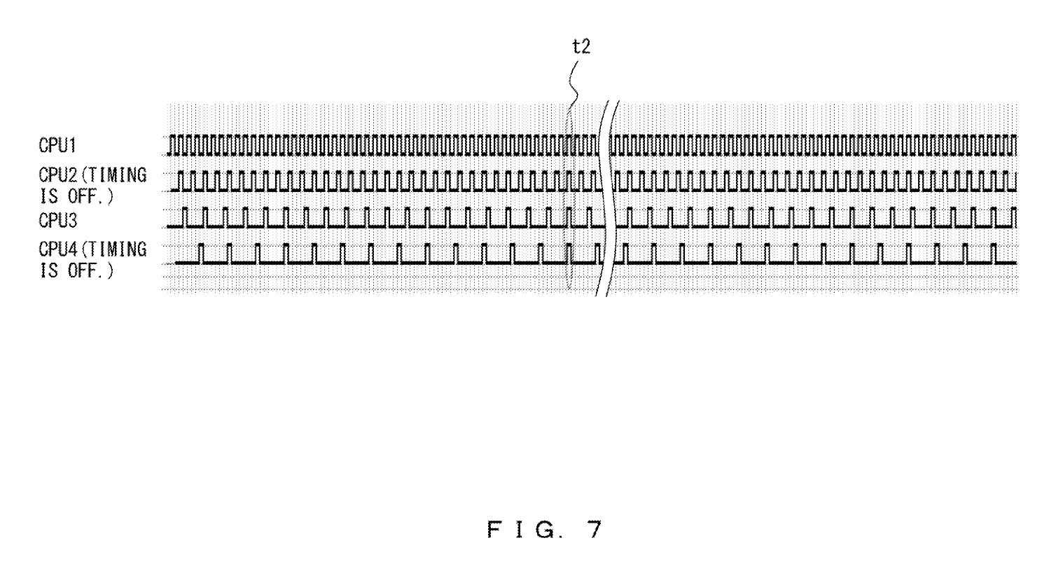

FIG. 6 and FIG. 7 are each a timing chart indicating an example of a time change in a state of each CPU. In FIG. 6 and FIG. 7, “CPU 1” to “CPU 4” indicate CPUs 101-0 to 101-3, respectively. In regard to the waveforms whose level changes in two steps, L (Low) and H (High), L indicates the stopped state and H indicates the in-operation state. In the case illustrated in FIG. 7, changes of states of the CPU 101-1 (or CPU 2) and the CPU 101-3 (or CPU 4) are behind those in the case illustrated in FIG. 6 by one time clock division (or one unit). Both FIG. 6 and FIG. 7 illustrate a case in which the execution interval b is common to all of the CPUs 101.

In the case illustrate in FIG. 6, after the current variation test is started, the in-operation states of the CPUs 101 are synchronized at time t1, i.e., the shifts of the CPUs 101 from the stopped state to the in-operation state are synchronized and the following shifts of the CPUs 101 from the in-operation state to the stopped state are synchronized at time t. In the case illustrated in FIG. 7, the in-operation states of the CPUs 101 are synchronized at time t2. As is clear from this fact, when the aforementioned cycle interval c is set to each CPU 101, the timing at which the shifts of the states are synchronized may occur even if each CPU 101 starts the current variation test at an optional timing.

When the CPUs 0101 simultaneously shift from the stopped state to the in-operation state, the maximum current variation in the direction of a current increase occurs. When the CPUs 0101 simultaneously shift from the in-operation state to the stopped state, the maximum current variation in the direction of a current decrease occurs. When one of the execution interval b and the stop interval a is common to all of the CPUs 101, the two kinds of maximum current variations occur within a short interval. Accordingly, the current variation test may be performed efficiently, and the state of the power supply unit 130 may be monitored more readily via the system control apparatus 15.

When the execution interval b is common to all of the CPUs 101, the two kinds of maximum current variations occur as described above in the order of: the maximum current variation in the direction of current increase→the maximum current variation in the direction of current decrease. By contrast, when the stop interval a is common to all of the CPUs 101, the two kinds of maximum current variations occur as described above in the order of: the maximum current variation in the direction of current decrease→the maximum current variation in the direction of current increase.

As a result, making one of the execution interval b and the stop interval a common to all of the CPUs 101 may control the timings of the occurrences of the two kinds of maximum currents. Accordingly, during the current variation test, the power supply unit 130 may be monitored in consideration of the timings of the occurrences.

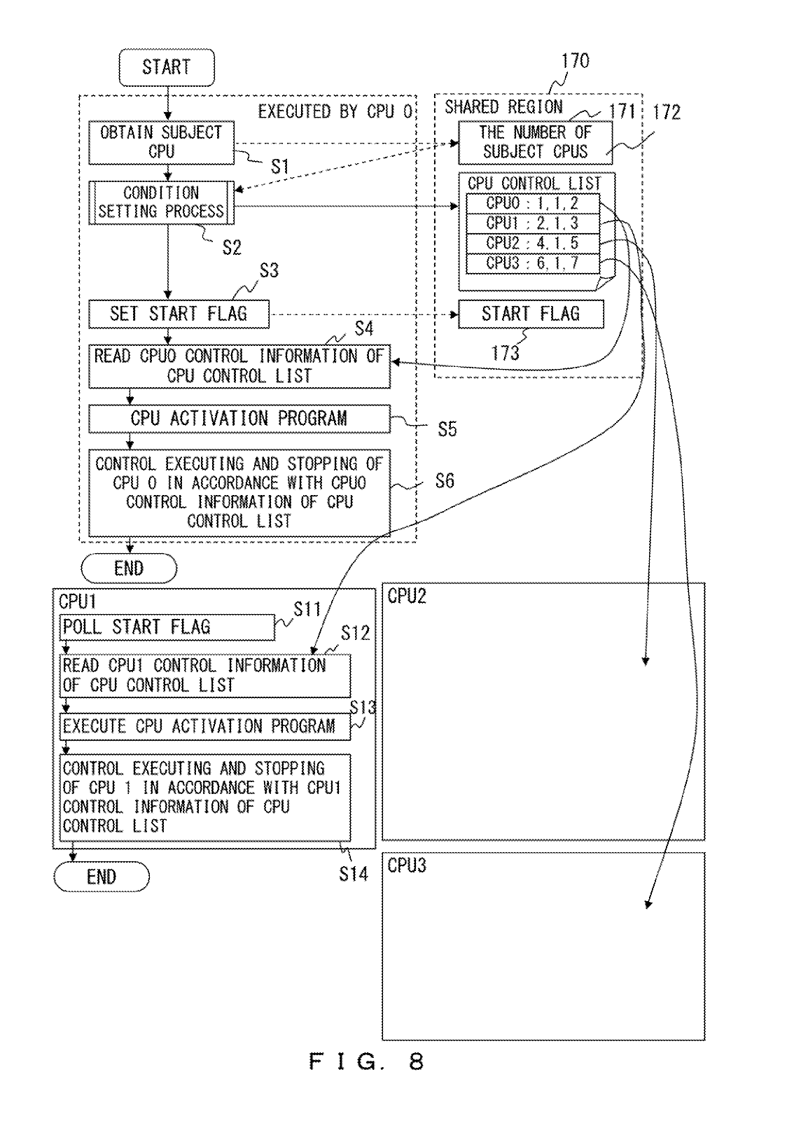

FIG. 8 is a flowchart indicating a flow of a process executed by each CPU in accordance with a test control program according to the present embodiment. Next, with reference to FIG. 8, operations achieved at the master CPU 101 and the slave CPUs 101 by the test control programs 140 and 150 will be described in detail.

The test control program 140 provides, for example, a user interface, and the operator gives an instruction to start or end the current variation test via the input apparatus 13. FIG. 8 indicates some of the operations executed upon the operator's instruction to start the current variation test.

First, the master CPU 101 (or the CPU core 201 of the master CPU 101) accesses the ROM 103 via the system bus 108 and obtains the hardware configuration information 160 stored in the ROM 103 (S1). The number of subject CPUs 171 is extracted from the obtained hardware configuration information 160 and stored in the shared region 170 of the shared memory 104 (S1). After the storing, the master CPU 101 executes a condition setting process of setting, to each CPU 101, the cycle interval c including the stop interval a and the execution interval b as a test condition (S2). Upon execution of the condition setting process, the CPU control list 172 is stored in the shared region 170.

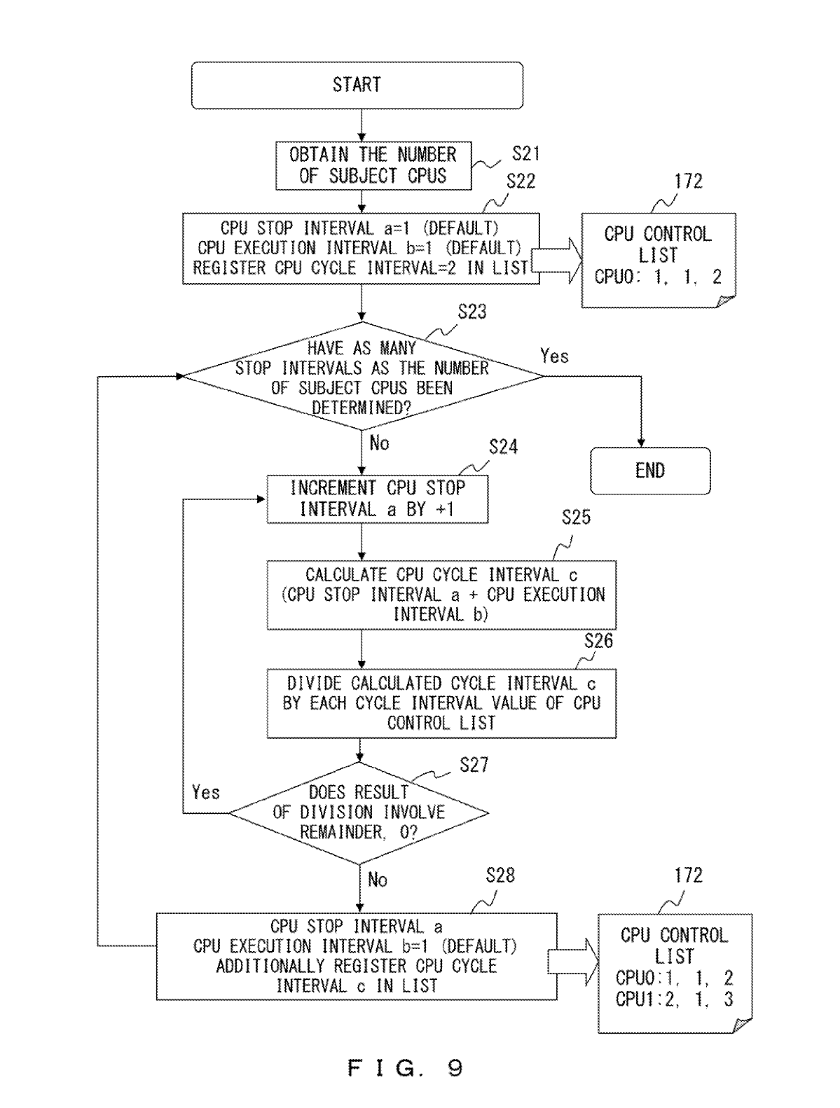

FIG. 9 is a flowchart of the condition setting process. Here, the condition setting process executed as S2 will be described in detail with reference to FIG. 9. The condition setting process is based on the premise that the execution interval b is common to the CPUs 101.

First, the master CPU 101 obtains the number of subject CPUs 171 by reading it from the shared region 170 (S21). The master CPU 101 then reserves a region for storage of the CPU control list 172 within the shared region 170 and stores (or registers) the CPU0 control information of itself in the CPU control list 172. At this moment, as the CPU0 control information, “1”, “1”, and “2” are respectively set to the stop interval (represented as “CPU stop interval” in FIG. 9) a, the execution interval (represented as “CPU execution interval” in FIG. 9) b, and the cycle interval (represented as “CPU cycle interval” in FIG. 9) c. All of these values are default values. “stop interval a”, “execution interval b”, and “cycle interval c” in FIG. 9 correspond to variables.

After this, the master CPU 101 determines whether or not as many stop intervals a have been determined as the number of subject CPUs 171 (S23). When the CPU control information corresponding to the number of subject CPUs 171 is generated, the judgment of “Yes” is indicated in S23 and the condition setting process ends. Meanwhile, when a CPU 101 for which CPU control information should be generated remains, the judgment of “No” is indicated in S23 and the process shifts to S24.

The master CPU 101, which has shifted to S24, increments the value of the stop interval a. Next, the master CPU 101 calculates the value of a corresponding cycle interval c after the incrementing of the value of the stop interval a (S25). The new value of the cycle interval c is obtained by adding the value of the stop interval a to the value of the execution interval b (cycle interval c=stop interval a+execution interval b).

Next, the master CPU 101 divides the value of the updated cycle interval c by the value of each of the cycle intervals c stored in the CPU control list 172 of the shared region 170 (S26). After this, the master CPU 101 determines whether or not the results of the divisions include a result involving the remainder, 0 (S27). The situation in which the value of the cycle interval c calculated in S26 is a multiple of the value of any of the cycle intervals c determined so far means that the results of the divisions include a result involving the remainder, 0. In this situation, accordingly, the judgment of “Yes” is indicated in S27 and the process returns to step S24 where the value of the stop interval a is further incremented. Meanwhile, the situation in which the ratio between the values of any two of the cycle intervals c determined so far, including the value of the cycle interval c calculated in S26, is represented by two integers that are coprime to each other, means that the results of the divisions do not include a result involving the remainder, 0, and hence the judgment of “No” is indicated in S27 and the process shifts to step S28.

The master CPU 101, which has shifted to S28, registers the execution interval b obtained in S22 and the stop interval a and the cycle interval c obtained in the immediate preceding steps S25 and S26 in the CPU control list 172 of the shared region 170 as the CPU control information of a current subject CPU 101. The process then returns to step S23.

In this way, in the condition setting process, pieces of CPU control information are sequentially generated for the CPUs 101 starting from a CPU 101 with the lowest CPU number, and these generated pieces of CPU information are registered (or stored) in the CPU control list 172. CPU control information registered in the CPU control list 172 involves the ratio between the values of any two cycle intervals c, which is represented by two different prime numbers. Accordingly, as illustrated in FIG. 6 and FIG. 7, the same state shifts of all of the CPUs 101 may be synchronized.

The aforementioned condition setting process is based on the premise that the execution interval b is common to the CPUs 101. The entire process flow will be basically the same as that in FIG. 9 even with the premise that the stop interval a is common to the CPUs 101. Setting each of the initial values of the values of the cycle intervals c at a value that is higher than two changes the ratio between the values of any two cycle intervals c represented by two different prime numbers into the ratio represented by two integers that are coprime to each other.

Descriptions will be given with reference to FIG. 8 again.

After the condition setting process, the process shifts to S3. The master CPU 101, which has shifted to S3, sets the start flag 173 of the shared region 170 (S3). Next, the master CPU 101 reads the CPU0 control information of itself stored in the CPU control list 172 of the shared region 170 (S5). In addition, the master CPU 101 executes (or starts) the CPU activation program 145 (S5). After this, the master CPU 101 stores the value of the cycle interval c of the CPU0 control information read in S4 in the register 203a of the timer interruption controller 203 and the register 204a of the CPU stop controller 204 (S6). In accordance with the stop interval a or the execution interval b of the CPU0 control information, the master CPU 101 controls count start timings of the counter 203b of the timer interruption controller 203 and the counter 204b of the CPU stop controller 204 (S6). In this way, in accordance with the CPU0 control information, the master CPU 101 makes a setting such that the master CPU 101 is stopped and operated repeatedly. After this, the processing series for starting the current variation test ends.

In the aforementioned processes, the process of S1 is achieved by the configuration determination unit 141 of the test control program 140. The condition setting process of S2 is achieved by the condition setting unit 142. The other processes are achieved by the test execution control unit 143. The test condition setting method in accordance with the present embodiment is achieved by the configuration determination unit 141 and the condition setting unit 142. The current variation testing method in accordance with the present embodiment is achieved by performing the processes by the configuration determination unit 141 and the condition setting unit 14 and then performing the processes by the test execution control unit 143.

Meanwhile, the CPU 101-1, which is a slave CPU 101, polls the start flag 171 stored in the shared region 170 on an as-needed basis (S11). When it is recognized in the polling that the start flag 171 has been set, the process shifts to S12, where the slave CPU 101 reads CPU1 control information of itself stored in the shared region 170. Next, the slave CPU 101 executes (or starts) the CPU activation program 145 (S13).

After this, the slave CPU 101 stores the value of the cycle interval c of the CPU1 control information read in S12 in the register 203a of the timer interruption controller 203 and the register 204a of the CPU stop controller 204. In accordance with the stop interval a or the execution interval b of the CPU0 control information, the slave CPU 101 controls count start timings of the counter 203b of the timer interruption controller 203 and the counter 204b of the CPU stop controller 204 (S14). In this way, as with the master CPU 101, in accordance with the CPU1 control information, the slave CPU 101 makes a setting such that the slave CPU 101 is stopped and operated repeatedly. After this, the processing series for starting the current variation test ends.

The aforementioned processes are similarly performed for other slave CPUs 101, the CPUs 101-2 and 101-3. Accordingly, processes performed by the other slave CPUs 101, the CPUs 101-2 and 101-3, will not be described.

After performing the processes for starting the current variation test as described above, the master CPU 101 monitors the coming of the end timing of the current variation test. The coming of the end timing indicates, for example, the passage of a test time that is set in advance or an operator giving an end instruction as described above. Upon the coming of the end timing, the master CPU 101 resets the start flag 173 and ends the CPU activation program 145.

After performing the processes for starting the current variation test as described above, the slave CPU 101 polls the start flag 173 to recognize resetting of the start flag 173. As a result, when the start flag 173 is reset, the CPU activation program 145 ends.

In the present embodiment, the correspondence between each CPU 101 and each piece of CPU control information is fixed, but the correspondence may be changed. That is, the current variation test may be performed a plurality of times by changing the correspondence between each CPU 101 and each piece of CPU control information. The correspondence may be changed in accordance with a rule established in advance or may be changed randomly.

In the present embodiment, the current variation test is directed to one information processing apparatus 1, but the test may be directed to a plurality of information processing apparatuses 1. That is, the current variation test may address a power supply unit that supplies a current to the plurality of information processing apparatuses 1. The configuration of the information processing apparatus 1 is not limited to that illustrated in FIG. 1.

In the present embodiment, a load on which software control is performed is the CPU 101, but, as long as software control may be performed on the load and the load may be stopped (power-off) and started (power-on) at an optional timing, the load does not need to be a CPU. Moreover, the current variation test may be directed to subjects including a load on which software control is not performed. Such a load may be the fan drive circuit 109 in the configuration in FIG. 1.

In the current variation test to which the present embodiment has been applied, the same kind of maximum current variations occur at particular time intervals. Accordingly, the time interval may be specified by, for example, the system control apparatus 15, and, in accordance with the passage of the specified time interval from the occurrence of a maximum current variation, the fan drive circuit 109 may be turned on or off. In this way, it is possible to cause a larger current variation when the current variation test is directed to loads to which currents are supplied from the same power supply unit and on which software control is not performed. Accordingly, the test is effective to confirm the power supply unit more properly.

As described above, the current variation test that causes the maximum variation in a current used by an information processing apparatus provided with a plurality of processors may be performed more readily by applying some embodiments of the present invention.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A test condition setting method for setting a condition of a current variation test that varies a current supplied from a power supply circuit provided in an information processing apparatus including a plurality of processors, the test condition setting method comprising:
setting lengths of cycle intervals of the plurality of processors used in the current variation test at lengths such that ratios between the lengths of the cycle intervals of the plurality of processors used in the current variation test become prime number ratios that are coprime to each other, the cycle intervals including operation intervals during which an in-operation state is maintained upon the processors being started one time and stop intervals during which a stopped state is maintained upon the processors being stopped one time; and
setting the lengths of the cycle intervals each set for each of the processors as the condition of the current variation test of the plurality of processors.

2. The test condition setting method according to claim 1, wherein
a length of one of the operation interval and the stop interval is common to the plurality of processors.

3. A current variation testing method for performing a current variation test that varies a current supplied from a power supply circuit provided in an information processing apparatus including a plurality of processors, the current variation testing method comprising:
setting, as a condition of the plurality of processors for the current variation test, lengths of cycle intervals of the plurality of processors at lengths allowing a ratio between lengths of cycle intervals of any two of the plurality of processors to be represented by two integers that are coprime to each other, the cycle intervals including operation intervals during which an in-operation state is maintained upon the processors being started one time and stop intervals during which a stopped state is maintained upon the central processing units being stopped one time; and
performing the current variation test by starting and stopping the plurality of processors in accordance with the set lengths of the cycle intervals.

4. The current variation testing method according to claim 3, wherein
a length of one of the operation interval and the stop interval is common to the plurality of processors.

5. An information processing apparatus provided with a plurality of processors, the information processing apparatus comprising:
a plurality of processors,
a storage apparatus having stored therein a program for causing the plurality of processors to execute a current variation testing process including,
starting and stopping the processors in accordance with condition data indicating, as lengths of cycle intervals of the plurality of processors, lengths allowing a ratio between lengths of cycle intervals of any two of the plurality of processors to be represented by two integers that are coprime to each other, the cycle intervals including operation intervals during which an in-operation state is maintained upon the processors being started one time and stop intervals during which a stopped state is maintained upon the processors being stopped one time.
